(19) United States
(12) Patent Application Publication
(10) Pub. No.: US 2008/0121947 A1
(43) Pub. Date: May 29, 2008

(54) Solar-powered MEMS acoustic sensor and system for providing physical security in a geographical area with use thereof

(76) Inventors: Robert Eugene Frahm, Flemington, NJ (US); Omar Daniel Lopez, Summit, NJ (US); Joseph Ashley Taylor, Springfield, NJ (US)

Correspondence Address: Lucent Technologies Inc.;Docket Administrator - Room 3J-219, 101 Crawfords Corner Road, Holmdel, NJ, 07733-3030, US

(21) Appl. No.: 11/520,965

(22) Filed: Sep. 14, 2006

(51) Int. Cl. H01L 29/84

(52) U.S. Cl. 257/254; 257/E29.324

(57) ABSTRACT

A MEMS microphone is fabricated into an integrated physical device which also comprises a solar cell. The solar cell provides power to the MEMS microphone, and may do so with use of a capacitor, which may also be incorporated into the device, and serves to provide power to the MEMS microphone when the solar cell is unable to do so (e.g., at night). A wireless transmitter and antenna may also be incorporated into the device, in order to transmit acoustic data which has been captured by the MEMS microphone. In one embodiment of the invention, the MEMS microphone comprises a fixed backplate and a diaphragm, and the solar cell is advantageously comprised in the diaphragm thereof.

### FIELD OF THE INVENTION

The present invention relates generally to the field of MEMS (micro-electromechanical systems) and more particularly to a MEMS acoustic sensor which is powered with the use of a solar cell and to a system for providing physical security in a geographical area with use thereof.

### BACKGROUND OF THE INVENTION

One possible mechanism for providing physical security in an open geographical area is to distribute a number of acoustic sensors—i.e., microphones—in and around the given area, in order to enable the detection of an intrusion via acoustical wave (i.e., sound) detection. In particular, such unattended acoustic sensors might be advantageously placed on the ground (which are then referred to as “ground sensors”), and may be advantageously placed at locations around the border of the given geographical area. In military applications, for example, it is often desirable to deploy such unattended ground sensors along the border or within an area of conflict in which improvised explosive devices (IEDs) may also be placed.

In both military and commercial applications, these sensors should advantageously be of a very small physical size so that they cannot be seen by intruders. Moreover, these sensors must necessarily have a source of power if they are to be able to receive acoustical waves and transmit acoustic signals. As such, one might naturally employ conventional batteries in order to power such devices.

For example, U.S. Pat. No. 6,967,362, “Flexible MEMS Transducer And Manufacturing Method Thereof, And Flexible MEMS Wireless Microphone,” issued on Nov. 22, 2005 to Yun-woo Nam et al., discloses a “flexible wireless MEMS microphone [which] includes a substrate of a flexible polymeric material, a flexible MEMS transducer structure formed on the substrate by PEVCD, an antenna printed on the substrate for communicating with an outside source, a wire and interface circuit embedded in the substrate to electrically connect the flexible MEMS transducer and the antenna, a flexible battery layer electrically connected to the substrate for supplying power to the MEMS transducer, and a flexible bluetooth module layer electrically connected to the battery layer.” (See U.S. Pat. No. 6,967,362, abstract.) Thus, U.S. Pat. No. 6,967,362 describes a small battery-powered MEMS acoustic sensor. U.S. Pat. No. 6,967,362 is hereby incorporated by reference as if fully set forth herein.

However, in many applications in which unattended acoustic ground sensors are used (especially, for example, in military applications), it may well be impractical to replace the devices or the batteries thereof on a periodic basis, a necessary requirement for any battery-powered device, such as the device disclosed in U.S. Pat. No. 6,967,362. Thus, it would be advantageous to have an unattended acoustic ground sensor which does not need to be periodically replaced or “serviced” (e.g., by replacing the battery thereof).

### SUMMARY OF THE INVENTION

In accordance with the principles of the present invention, a MEMS microphone is fabricated into an integrated physical device which also comprises a solar cell. The solar cell advantageously provides power to the MEMS microphone, and, in accordance with certain illustrative embodiments of the present invention, does so with use of a capacitor, which is also advantageously incorporated into the device. In embodiments of the present invention which include a capacitor, the capacitor advantageously serves to provide power to the MEMS microphone when the solar cell is unable to do so (e.g., at night).

In accordance with certain illustrative embodiments of the present invention, a wireless transmitter and antenna are also incorporated into the device, in order to transmit acoustic data which has been captured by the MEMS microphone. And, moreover, in accordance with one illustrative embodiment of the present invention, the MEMS microphone comprises a fixed backplate and a diaphragm, and the solar cell is advantageously comprised in the diaphragm thereof.

### BRIEF DESCRIPTION OF THE DRAWINGS

FIG. 1 shows a diagram of the electrical structure of a solar-powered MEMS acoustic sensor in accordance with an illustrative embodiment of the present invention.

FIG. 2 shows a diagram showing one possible physical structure of a solar-powered MEMS acoustic sensor in accordance with an illustrative embodiment of the present invention.

FIG. 3 shows a geographical area having a plurality of solar-powered MEMS acoustic sensors distributed on the border thereof to provide physical security therefor in accordance with an illustrative embodiment of the present invention.

### DETAILED DESCRIPTION OF THE PREFERRED EMBODIMENTS

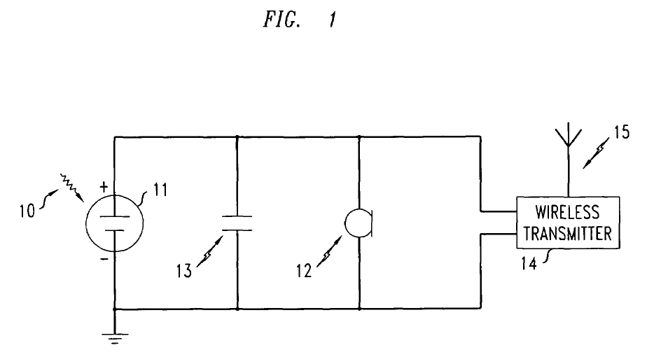

FIG. 1 shows a diagram of the electrical structure of a solar-powered MEMS acoustic sensor in accordance with an illustrative embodiment of the present invention. The illustrative solar-powered MEMS acoustic sensor comprises solar cell 11, MEMS microphone (i.e., transducer) 12, capacitor 13, wireless transmitter 14 and antenna 15. In operation, solar cell 11 produces power from incident solar rays 10 (which contain solar energy) and stores the generated power in capacitor 13 which, in turns, provide the necessary power to MEMS microphone 12 and wireless transmitter 14. Thus, MEMS microphone 12 will advantageously pick up any sound in its immediate vicinity, generating an acoustic signal which may then be transmitted over the air by wireless transmitter 14 with use of antenna 15.

Note that the use of capacitor 13 advantageously allows the illustrative solar-powered MEMS acoustic sensor to operate at night and during other periods of time where there is insufficient sunlight to stimulate the solar cell to generate power. And in accordance with one illustrative embodiment of the present invention, wireless transmitter 14 is advantageously activated (and thereby transmits the acoustic signal) only when MEMS microphone 12 has actually detected the presence of sound (i.e., when the acoustic signal power is above a minimal threshold), thereby indicating the possible presence of an intruder.

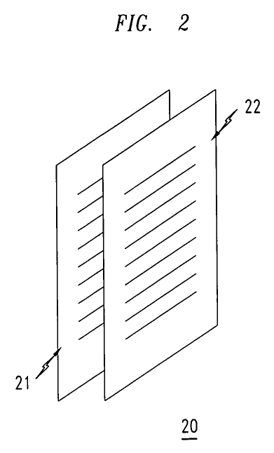

FIG. 2 shows a diagram showing one possible physical structure of a solar-powered MEMS acoustic sensor in accordance with an illustrative embodiment of the present invention. In accordance with the illustrative embodiment as shown in the figure, MEMS microphone 20 comprises backplate 21 and diaphragm 22. As is well known to those skilled in the art, a microphone (i.e., transducer) may be implemented by a fixed backplate and a moveable diaphragm which operates (i.e., moves back and forth) as a result of sound (i.e., acoustic waves) which impinges upon it. This movement of the diaphragm (in response to acoustic waves) thus generates an acoustic signal representative of the sound.

In accordance with the illustrative embodiment of the present invention shown in FIG. 2, however, diaphragm 22 also comprises a solar cell. Thus, advantageously, solar rays which impinge on diaphragm/solar cell 22 provide power for the operation of MEMS microphone 20, while acoustic waves (i.e., sound) which impinge on diaphragm/solar cell 22 produce the acoustic signal representative of the sound. In accordance with certain illustrative embodiments of the present invention, a capacitor (not shown in FIG. 2) is also provided in order to store power for use during times when the solar cell is not operational (e.g., at night) due to the lack of solar rays impinging thereupon. (See discussion of FIG. 1 above.)

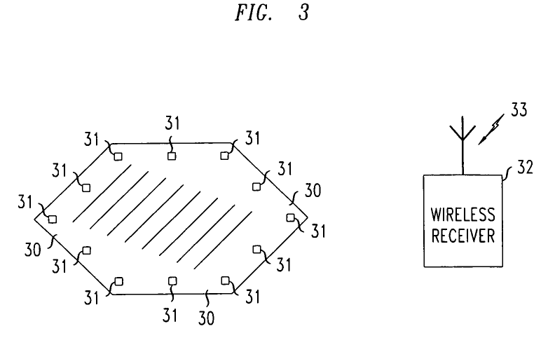

FIG. 3 shows a geographical area having a plurality of solar-powered MEMS acoustic sensors distributed on the border thereof to provide physical security therefor in accordance with an illustrative embodiment of the present invention. Specifically, as shown in the figure, a sufficient number of solar-powered MEMS acoustic sensors 31 are distributed near the periphery of geographical area 30 such that the sound made by an intruder will be captured by one of the MEMS microphones comprised therein. Advantageously, the plurality of solar-powered MEMS acoustic sensors are hidden from view—for example, concealed in grass or slightly buried in the soil—so that an intruder is unaware of their existence. The appropriate number of solar-powered MEMS acoustic sensors distributed around the geographical area will obviously depend on the physical size of the area and the sensitivity of the sensors, and will be easily determinable by one of ordinary skill in the art.

As is also shown in FIG. 3, wireless receiver 32, having antenna 33, is (preferably) located outside of the geographical area which is being protected. In operation, wireless receiver 32 receives, via antenna 33, transmissions from any of the solar-powered MEMS acoustic sensors distributed in the geographical area and thereby identifies the presence of an intruder in the area. In certain illustrative embodiments of the present invention, the (approximate) location of an intruder may be advantageously determined by wireless receiver 32 (or a separate processor operating in cooperation therewith) based on which solar-powered MEMS acoustic sensors 31 have detected sound from the intruder.

It will be obvious to those skilled in the art that the solar-powered MEMS acoustic sensors described above may be physically implemented in numerous ways, most preferably by fabricating the elements of each such acoustic sensor (i.e., a solar cell and MEMS microphone, as well as, possibly, a capacitor, and also, possibly, a wireless transmitter and antenna) into a single integrated device. For example, these elements may be advantageously integrated into a substrate, which may, for example, comprise a semiconductor substrate, a dielectric substrate, or a crystalline silicon substrate, each of which is fully familiar to those of ordinary skill in the art. The design and fabrication of each of these possible implementations will be fully obvious to those skilled in the art.

### Addendum to the Detailed Description

It should be noted that all of the preceding discussion merely illustrates the general principles of the invention. For example, it will be obvious to one skilled in the art to design specific physical and electrical implementations of the above-described device in accordance with the principles of the invention in order to create particular devices which embody the inventive concept described herein. It will also be appreciated that those skilled in the art will be able to devise various other arrangements, which, although not explicitly described or shown herein, embody the principles of the invention, and are included within its spirit and scope. In addition, all examples and conditional language recited herein are principally intended expressly to be only for pedagogical purposes to aid the reader in understanding the principles of the invention and the concepts contributed by the inventor to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. It is also intended that such equivalents include both currently known equivalents as well as equivalents developed in the future—i.e., any elements developed that perform the same function, regardless of structure.

1. An apparatus comprising:
a solar cell for collecting solar energy; and
a MEMS microphone integrated together with said solar cell into a single physical device, the MEMS microphone powered with use of said solar energy collected by said solar cell,
wherein said MEMS microphone comprises said solar cell as a portion thereof,
wherein said MEMS microphone comprises a fixed backplate and a diaphragm, and
wherein said diaphragm comprises said solar cell.

2. (canceled)

3. (canceled)

4. The apparatus of claim 4 further comprising:
a capacitor connected to power the MEMS microphone, the solar cell being connected to the capacitor to charge the capacitor with use of said solar energy collected thereby.

5. The apparatus of claim 4 further comprising:
a wireless transmitter configured to transmit data captured by the MEMS microphone.

6. The apparatus of claim 5 further comprising:
an antenna connected to said wireless transmitter for use in transmitting said data captured by the MEMS microphone.

7. The apparatus of claim 1 wherein the solar cell and the MEMS microphone are integrated into a substrate.

8. The apparatus of claim 7 wherein the substrate comprises a semiconductor substrate.

9. The apparatus of claim 7 wherein the substrate comprises a dielectric substrate.

10. The apparatus of claim 7 wherein the substrate is a crystalline silicon substrate.

11. A system for providing physical security in a geographical area comprising a plurality of devices distributed within said geographical area, each of said devices comprising:
a solar cell for collecting solar energy; and
a MEMS microphone integrated together with said corresponding solar cell into a single physical device, the MEMS microphone powered with use of said solar energy collected by said solar cell,
wherein said MIEMS microphone comprised in each of said devices comprises said corresponding solar cell as a portion thereof,
wherein said MEMS microphone comprised in each of said devices comprises a fixed backplate and a diaphragm, and
wherein said diaphragm of each of said MEMS microphones comprises said corresponding solar cell.

12. (canceled)

13. (canceled)

14. The system of claim 11 wherein each of said devices further comprises:
a capacitor connected to power the MEMS microphone, the corresponding solar cell being connected to the capacitor to charge the capacitor with use of said solar energy collected thereby.

15. The system of claim 14 wherein each of said devices further comprises:
a wireless transmitter configured to transmit data captured by the corresponding MEMS microphone; and
an antenna connected to said corresponding wireless transmitter for use in transmitting said data captured by the corresponding MEMS microphone.

16. The system of claim 11 wherein the solar cell and the MEMS microphone comprised in each of said devices are integrated into a corresponding substrate.

17. The system of claim 16 wherein each of said substrates comprises a semiconductor substrate.

18. The system of claim 16 wherein each of said substrates comprises a dielectric substrate.

19. The system of claim 16 wherein each of said substrates is a crystalline silicon substrate.

20. The system o:F claim 11 wherein said plurality of devices are distributed near a geographical boundary surrounding said geographical area.
